(19) United States
(12) Patent Application Publication
(10) Pub. No.: US 2014/0035447 A1
(43) Pub. Date: Feb. 6, 2014

(54) DEVICE HOUSING AND MANUFACTURING METHOD

(71) Applicants: SHENZHEN FUTAIHONG PRECISION INDUSTRY CO., LTD., (US); FIH (HONG KONG) LIMITED, Kowloon (HK)

(72) Inventors: YA-HUI WANG, Shenzhen (CN); YONG-GANG ZHANG, Shenzhen (CN); KUAN-HUNG CHEN, Shindian (TW)

(73) Assignees: FIH (HONG KONG) LIMITED, Kowloon (HK); SHENZHEN FUTAIHONG PRECISION INDUSTRY CO., LTD., Shenzhen (CN)

(21) Appl. No.: 13/889,565

(22) Filed: May 8, 2013

(30) Foreign Application Priority Data
Aug. 6, 2012 (CN) 2012102767945

(51) Int. Cl. H05K 5/06

(52) U.S. Cl. CPC H05K 5/061
USPC 312/223.1; 264/255

(57) ABSTRACT

A device housing includes a first supporting part, a second supporting part and a sealing module. The first supporting part defines a hole. The second supporting part is integral with the first supporting part and the second supporting part functions as a light guide plate. The sealing module includes a first gasket, a second gasket, and a third gasket, the first gasket positioned on the first supporting part, the second gasket positioned a peripheral edge of the hole, the third gasket positioned at one end of the first supporting part.

### BACKGROUND

1. Technical Field

The present disclosure generally relates to housing manufacturing, and particularly to a device housing for supporting a liquid display module and a keypad module, and a method for manufacturing the housing.

2. Description of Related Art

In portable electronic devices, liquid crystal displays and keypads often each need their own respective housing to be supported. Using several housings may make miniaturization of devices difficult, and may increase production costs.

Therefore, there is room for improvement within the art.

### BRIEF DESCRIPTION OF THE DRAWINGS

Many aspects of the housing and the method for manufacturing the housing can be better understood with reference to the following drawings. The components in the drawings are not necessarily to scale, the emphasis instead being placed upon clearly illustrating the housing and the method for manufacturing the housing. Moreover, in the drawings, like reference numerals designate corresponding parts throughout the several views.

FIG. 1 is a schematic view of an exemplary embodiment of a housing.

FIG. 2 is similar to FIG. 1, but shown from another aspect.

FIG. 3 is an exploded of the housing of FIG. 1.

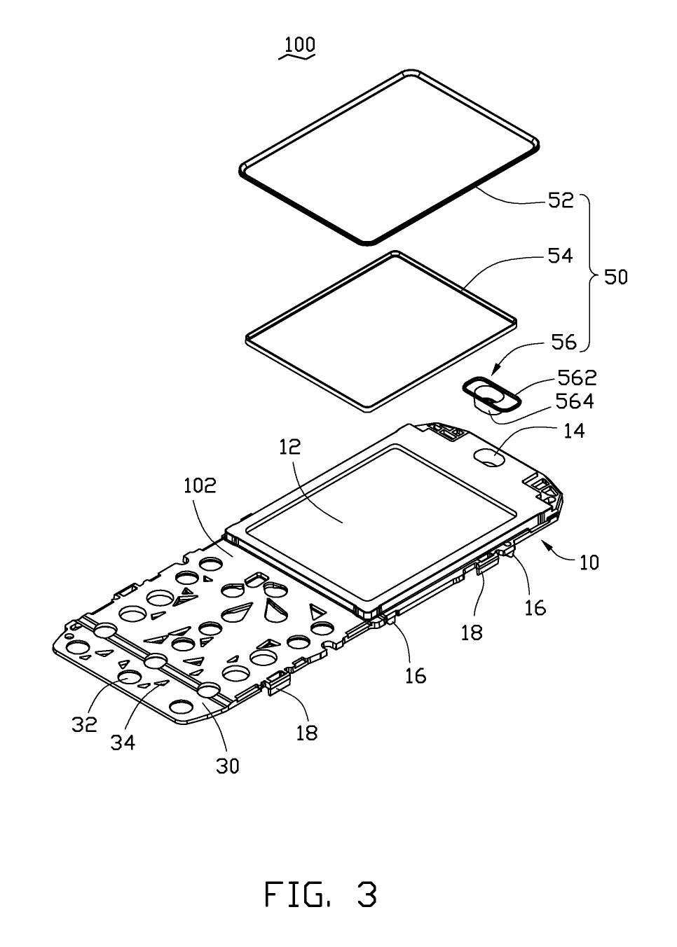

### DETAILED DESCRIPTION

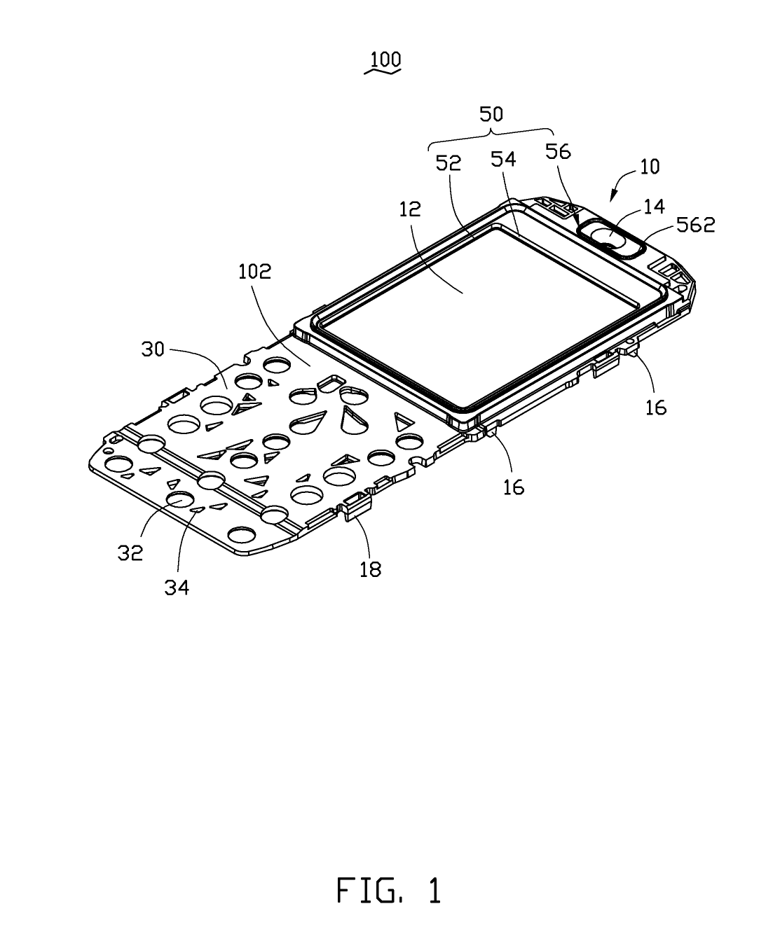

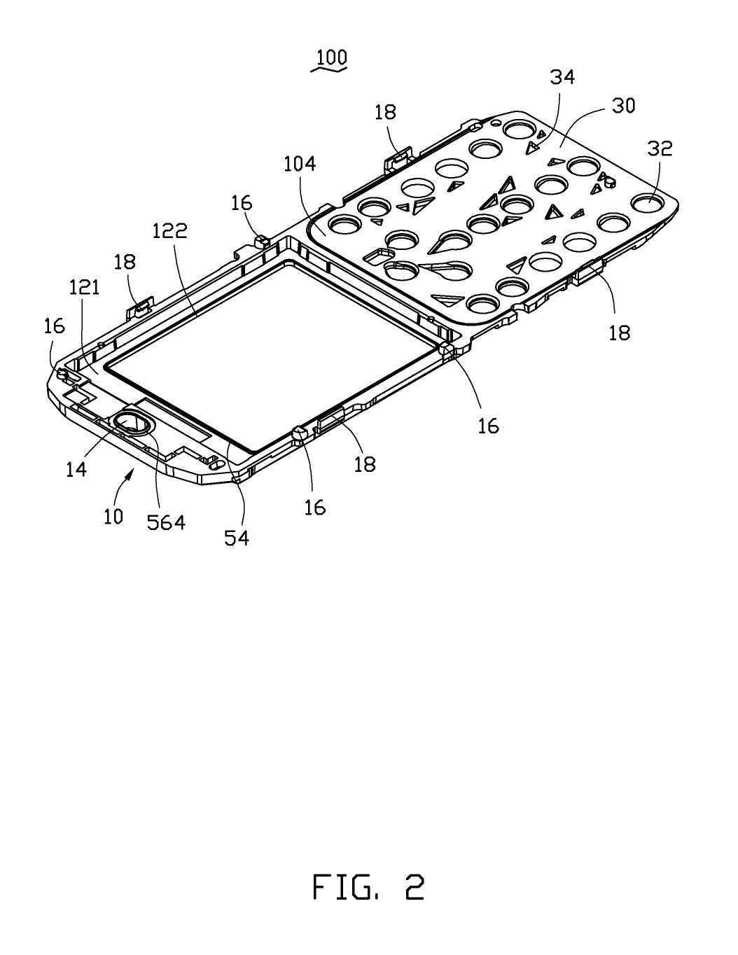

FIG. 1 and FIG. 2 show an exemplary embodiment of a housing 100. The housing 100 is assembled into a portable electronic device and is an integral member. The housing 100 includes a first supporting part 10, a second supporting part 30, and a sealing module 50 integrally formed together.

The first supporting part 10 is for supporting a liquid display module (not shown). The second supporting part 30 functions as a light guide plate, and is for supporting a keypad module (not shown). The sealing module 50 is integrally formed on the first supporting part 10.

The first supporting part 10 and the second supporting part 30 are made of the same material. In the exemplary embodiment, the first supporting part 10 and the second supporting part 30 are made of transparent material such as plastic, e.g, polycarbonate (PC). The housing 100 includes a first surface 102 and a second surface 104. The first supporting part 10 at one side of the first surface 102 is slightly higher than the second supporting part 30, and defines a rectangular receiving hole 12 with a peripheral edge 122. A microphone hole 14 is defined in one end of the first supporting part 10 distant from the second supporting part 30. The first supporting part 10 at the side of the second surface 104 defines a rectangular receiving groove 121 for receiving the liquid display module. The size of the area of the receiving groove 121 is larger than the size of the area of the receiving hole 12. At least one positioning block 16 is formed on the first supporting part 10 for positioning the housing 100 to a back housing of a portable electronic device. In the exemplary embodiment, there are four positioning blocks 16 around the receiving groove 121. At least one hook 18 is formed on the first supporting part 10 and the second supporting part 30 for latching the housing 100 to the back housing of a portable electronic device. In the exemplary embodiment, there are four hooks 18, one pair of hooks 18 positioned at opposite sides of the first supporting part 10 and another pair of hooks 18 positioned at opposite sides of the second supporting part 30.

The second supporting part 30 is used for illuminating a keypad of the portable electronic device. The second supporting part 30 has a generally grid-like configuration and includes an array of apertures 32. The apertures 32 correspond to the shapes of keys (not shown). When the keys are located within the apertures 32, light can readily be directed into the keys from the second supporting part 30. A plurality recesses 34 are defined among the apertures 32. A peripheral wall of each recess 34 functions as a reflecting surface and as a transmitting surface. The reflecting surfaces are for optimum reflection so that the light can be uniformly transmitted farther.

The sealing module 50 includes a first gasket 52, a second gasket 54 and a third gasket 56. The first gasket 51, the second gasket 54 and the third gasket 56 are each made of thermoplastic polyurethane (TPU) and are integrally formed with the first supporting part 10 and the second supporting part 30. The first gasket 52 is formed around the hole 12. An area of the first gasket 52 is larger than the area of the hole 12. The first gasket 52 seals the housing 100 with a front housing of the portable electronic device. The second gasket 54 is formed on the peripheral edge 122 of the hole 12 and seals against the liquid crystal module. The third gasket 56 is formed around the microphone hole 14 and includes a first edge 562 and a second edge 564. The first edge 562 seals the housing 100 with the front cover around a microphone of the portable electronic device. The second edge 564 seals the housing 100 with a printed circuit board around a microphone of the portable electronic device.

The housing 100 includes an integral first supporting part 10 and the second supporting part 30 to simplify the number of the assembled components. The first gasket 52 can effectively seal between a front cover and the housing 100. The second gasket 54 seals against the LCD module. The third gasket 56 seals the front cover with the housing 100 at one side and seal the printed circuit board and the housing at another side.

A method for manufacturing the housing 100 is described as follows.

An injection mold is provided. A first molding material is injected into the molding cavity to form the first supporting part 10 and the second supporting part 30. In the exemplary embodiment, the first molding material is made of PC. After that, a second molding material is injected into the molding cavity and integrally combines the first supporting part 10 and the second supporting part 30 to form the housing 100. In the exemplary embodiment, the second molding material is made of TPU. The TPU molding material forms the predetermined shaped sealing module 50. Finally, the housing 100 is removed from the mold cavity.

The first supporting part 10, the second supporting part 30 and the sealing module 50 are integrally formed together by the above method. The method for manufacturing the device housing 10 by injection molding increases processing efficiency and reduces production time. Additionally, the sealing module is stably positioned on the housing 100 and has a good seal.

It is to be understood, however, that even through numerous characteristics and advantages of the present disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A device housing comprising:
a first supporting part defining a hole;
a second supporting part being integral with the first supporting part, the second supporting part functioning as a light guide plate; and
a sealing module comprising a first gasket, a second gasket, and a third gasket, the first gasket is positioned on the first supporting part, the second gasket is positioned a peripheral edge of the hole, the third gasket is positioned at one end of the first supporting part.

2. The device housing as claimed in claim 1, wherein the first supporting part and the second supporting part are made of polycarbonate.

3. The device housing as claimed in claim 2, wherein at least one positioning block is formed on the first supporting part for positioning the housing to a back housing of a portable electronic device.

4. The device housing as claimed in claim 1, wherein the second supporting part has a generally grid-like configuration and includes an array of apertures, a plurality of recesses are defined among the apertures.

5. A method for manufacturing a device housing, comprising:
injecting a first molten material into a molding cavity of an injection mold to form a first supporting part and a second supporting part;
injecting a second molten material to the first supporting part to form a sealing module bonded to the housing.

6. The method as claimed in claim 5, wherein the first supporting part and the second supporting part are made of polycarbonate.

7. The method as claimed in claim 6, wherein at least one positioning block is formed on the first supporting part for positioning the housing to a back housing of a portable electronic device.

8. The method as claimed in claim 6, wherein the second supporting part has a generally grid-like configuration and includes an array of apertures and a plurality of recesses are defined among the apertures.
